(19) United States
(12) Patent Application Publication
(10) Pub. No.: US 2020/0315023 A1
(43) Pub. Date: Oct. 1, 2020

(54) COPPER INTERFACE FEATURES FOR HIGH SPEED INTERCONNECT APPLICATIONS

(71) Applicant: Intel Corporation, Santa Clara, CA (US)

(72) Inventors: Suddhasattwa NAD, Chandler, AZ (US); Kassandra NIKKHAH, Mesa, AZ (US); Joshua MICHALAK, Peoria, AZ (US); Marcel WALL, Phoenix, AZ (US); Rahul MANEPALLI, Chandler, AZ (US); Cemil GEYIK, Gilbert, AZ (US); Benjamin DUONG, Chandler, AZ (US); Darko GRUJICIC, Chandler, AZ (US)

(21) Appl. No.: 16/363,925

(22) Filed: Mar. 25, 2019

(51) Int. Cl. H05K 3/10; H01L 23/538; H05K 1/11; H01L 23/498; H01L 21/48

(52) U.S. Cl. CPC H05K 3/108; H01L 23/5386; H05K 1/11; H01L 23/49838; H05K 2203/0548; H05K 2201/0379; H05K 2201/0352; H05K 2203/0723; H01L 21/4846

(57) ABSTRACT

Embodiments disclosed herein include electronic packages and methods of forming such packages. In an embodiment, the electronic package comprises a first layer of a package substrate and a conductive trace over the first layer of the package substrate. In an embodiment, the conductive trace comprises a conductive body with a first surface over the first layer of the package substrate, a second surface opposite the first surface, and sidewall surfaces coupling the first surface to the second surface. In an embodiment, the second surface has a first roughness and the sidewall surfaces have a second roughness that is less than the first roughness.

### TECHNICAL FIELD

Embodiments of the present disclosure relate to electronic packaging, and more particularly, to electronic packages with nano-roughened copper surfaces and methods of forming such electronic packages.

### BACKGROUND

Substrates for next generation chip-to-chip interconnect technologies require significantly high speed and higher density input/output (I/O) routing. Accordingly, next generation packaging solutions are trending to higher I/O densities to meet the rapidly increasing demand for greater connectivity and faster speeds. This drives the electronic packaging roadmap to deliver ever more complex packages with embedded silicon dies and/or multi-chip enabled packages. One particular issue that arises with such architectures is that the surface roughness of the traces starts playing a significant role in the signal losses at high frequencies. As the surface roughness of the traces increases, the signal losses also increase.

However, surface roughness in the traces is currently needed in order to provide high reliability. In currently available electronic packages, the copper traces are roughened to create micro-roughened copper for improving adhesion between the copper and the dielectric material. The micro-roughened copper typically has an average depth of valleys (Rv) that is between 2 μm-10 μm. This delivers a reliable package, but provides poor electrical performance as evidenced by high insertion loss characteristics.

Accordingly, improving the adhesion of the dielectric material to smooth copper surfaces is an area of interest for improving electronic packages. For example, spray or dip equipment based deposition of organic adhesion promoters in conjunction with low amplitude micro-roughened copper has been proposed. Such solutions rely on intermolecular polymerization to form polymerized layers on the copper surface. While such solutions deliver some benefit to the insertion loss characteristics, this solution still provides reduced package reliability. Additionally, the adhesion promoters need to be customized for different dielectric materials.

### BRIEF DESCRIPTION OF THE DRAWINGS

FIG. 1A is a cross-sectional illustration of a conductive trace with a bimetallic film over a top surface, in accordance with an embodiment.

FIG. 1B is a cross-sectional illustration of the conductive trace in FIG. 1A after the bimetallic film is selectively etched to remove one of the metallic components in order to provide a nanoroughened surface, in accordance with an embodiment.

FIG. 2 is an illustration of a microstructure of a nanoroughened surface of a conductive trace, in accordance with an embodiment.

FIG. 3A is a cross-sectional illustration of a first dielectric layer with a seed layer, in accordance with an embodiment.

FIG. 3B is a cross-sectional illustration after a resist layer is disposed over the seed layer and patterned to provide a plurality of openings, in accordance with an embodiment.

FIG. 3C is a cross-sectional illustration after conductive traces with a main body and a bimetallic film is disposed in each of the openings, in accordance with an embodiment.

FIG. 3D is a cross-sectional illustration after the resist layer is removed, in accordance with an embodiment.

FIG. 3E is a cross-sectional illustration of one of the conductive traces that more clearly illustrates the structure of the bimetallic film, in accordance with an embodiment.

FIG. 3F is a cross-sectional illustration after exposed portions of the seed layer are removed, in accordance with an embodiment.

FIG. 3G is a cross-sectional illustration after the bimetallic layer is selectively etched to provide a nanoroughened surface on the conductive trace, in accordance with an embodiment.

FIG. 3H is a cross-sectional illustration of one of the conductive traces that more clearly illustrates the nanoroughened surface, in accordance with an embodiment.

FIG. 3I is a cross-sectional illustration after a second dielectric layer is disposed over the conductive traces and the first dielectric layer, in accordance with an embodiment.

FIG. 3J is a cross-sectional illustration of one of the conductive traces that more clearly illustrates the second dielectric layer conforming to the nanoroughened surface, in accordance with an embodiment.

FIG. 4 is a cross-sectional illustration of an electronic system that comprises an electronic package with nanoroughened conductive traces, in accordance with an embodiment.

FIG. 5 is a schematic of a computing device built in accordance with an embodiment.

### EMBODIMENTS OF THE PRESENT DISCLOSURE

Described herein are electronic packages with nano-roughened copper surfaces and methods of forming such electronic packages, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, high signaling speeds in advanced electronic packaging architectures is leading towards the need to reduce the surface roughness of conductive traces. However, reduced surface roughness leads to poor package reliability due to poor adhesion between the dielectric layers and the smooth conductive traces. Accordingly, embodiments disclosed herein include a high-frequency low-amplitude nanoroughened surface. Such surfaces enable the high speed interconnects needed for advanced packaging architectures without sacrificing the reliability of the electronic package.

Particularly, embodiments disclosed herein provide a bimetallic layer disposed over the main body of the conductive trace. The bimetallic layer comprises a first metallic material and a second metallic material that is different than the first metallic material. The second metallic material is selectively etched relative to the first metallic material in order to provide a porous film of the first metallic material. The low-amplitude of the surface (e.g., an average depth of valleys (Rv) that is less than 2 μm) provides improved insertion loss characteristics, and the adhesion to the dielectric material is still adequate due to the high-frequency of the peaks and valleys (e.g., an average width of the peaks and valleys may be 50 nm or less). Furthermore, the amplitude and frequency can be tuned by controlling the gradient deposition profile of the bimetallic film layer. Additionally, embodiments disclosed herein are enabled with existing materials and toolsets (e.g., etching chemistries, plating processes, lithography tools, and the like). Accordingly, further capital investment may be limited or eliminated in order to implement embodiments disclosed herein.

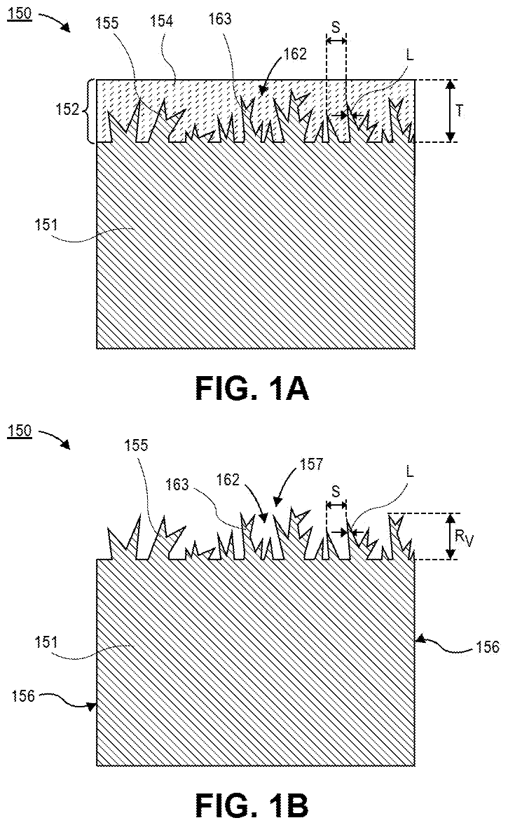

Referring now to FIG. 1A, a cross-sectional illustration of a conductive trace 150 is shown, in accordance with an embodiment. The conductive trace 150 may comprise a main body 151 and a film 152 over the main body. The film 152 may be a bimetallic film. That is, the film 152 may comprise a first metallic material 155 and a second metallic material 154. In some embodiments, the first metallic material 155 may be the same material as the main body 151. The second metallic material 154 may be a metallic material that has can be selectively etched away with an etching chemistry (as will be disclosed in greater detail below). For example, the first metallic material 155 may be copper and the second metallic material 154 may be zinc, tin, or nickel.

As shown, in FIG. 1A, the first metallic material 155 may have a textured surface that is conformally filled with the second metallic material 154. In a particular embodiment, the film 152 may exhibit a microstructure with defined boundaries between the first metallic material 155 and the second metallic material 154. In other embodiments, the first metallic material 155 and the second metallic material 154 may have at least some degree of alloying between the two materials. In FIG. 1A, the boundary between the first metallic material 155 and the second metallic material 154 is shown as being a distinct boundary in order to not obscure embodiments disclosed herein.

In an embodiment, the first metallic material 155 may have a plurality of ligaments 163 and pores 162. The ligaments 163 may be characterized with an average width L, and the pores 162 may have an average width S. For example, the pores 162 may have an average width S that is less than 50 nm and the ligaments 163 may have an average width that is less than 50 nm. In other embodiments, the average width S of the pores 162 may be 10 nm or less, and the average width L of the ligaments 163 may be 10 nm or less. In an embodiment, the average width S of the pores 162 may be substantially equal to an average width L of the ligaments 163. In other embodiments, the average width S of the pores 162 may be different than the average width L of the ligaments 163.

The morphology of the film 152 (i.e., the microstructure of the first metallic material 155 and the second metallic material 154) may be controlled by modulating processing conditions during a plating process (e.g., an electrolytic plating process) used to form the film 152. For example, the volume percentage of the first metallic material 155 may decrease with respect to greater Z-heights in the film 152. That is, a bottom portion of the film 152 proximate to the main body 151 of the conductive trace 150 may have a higher volume percentage of the first metallic material 155 compared to a top portion of the film 152 opposite from the main body 151 of the conductive trace 150.

In an embodiment, the film 152 may have a thickness T. The thickness T may be chosen in order to provide a desired surface morphology after the second metallic material is removed. For example, increasing the thickness T may increase an average depth of valleys Rv of the first metallic material 155. In an embodiment, the thickness T may be 5 μm or less, 2 μm or less, or 1 μm or less.

Referring now to FIG. 1B, a cross-sectional illustration of the conductive trace 150 after the second metallic material 154 is removed is shown. In an embodiment, the second metallic material 154 may be removed with an etching process that selectively removes the second metallic material 154 relative to the first metallic material 155. The removal of the second metallic material 154 provides a top surface 157 that is nanoroughened.

Due to the selectivity of the etching process to the second metallic material 154, only the top surface 157 is provided with a nanoroughened surface. Particularly, the top surface 157 may have a surface roughness that is greater than a surface roughness of sidewall surfaces 156 of the main body 151. Such embodiments are particularly beneficial with improving the electrical performance of the conductive trace 150, because less of the overall surface is roughened (compared to typical copper roughening processes currently used which roughen the top surface and the sidewall surfaces). Accordingly, embodiments disclosed herein exhibit reduced insertion losses and enables the high speed data transfers needed for advanced packaging architectures, such as embedded multi-die interconnect bridge (EMIB), etc.

In an embodiment, the surface roughness of the top surface 157 may be characterized as having a high-frequency and low amplitude. Particularly, the amplitude (i.e., the average depth of valleys (Rv)) may be correlated to the thickness T of the film 152. As such, the average depth of valleys Rv may be as high as 5 μm or 1 μm or less. This is a significantly smaller amplitude than is possible with existing copper roughening processes (e.g., wet chemistry based copper roughening with metal etch) which can only provide Rv values greater than 2 μm. Reduced amplitude roughening typical of embodiments disclosed herein further reduces insertion losses and, therefore, improves electrical performance.

While amplitude is decreased, it is to be appreciated that adhesion is not sacrificed. Particularly, the increased frequency of the ligaments 163 and pores 162 (e.g., due to the reduction in the average widths L and S) provides increased adhesion relative to existing copper roughening processes (e.g., wet chemistry based copper roughening with metal etch). Existing processes can only provide frequencies that are approximately 1 μm or greater, and embodiments disclosed herein provide frequencies that are orders of magnitude smaller. As noted above, the high-frequency features are provided since the average widths L and S are orders of magnitude may be 50 nm or less, or 10 nm or less. Accordingly, embodiments disclosed herein provide a nanoroughened surface that has reduced amplitude (in order to improve electrical performance) while at the same time have a high-frequency (in order to increase adhesion).

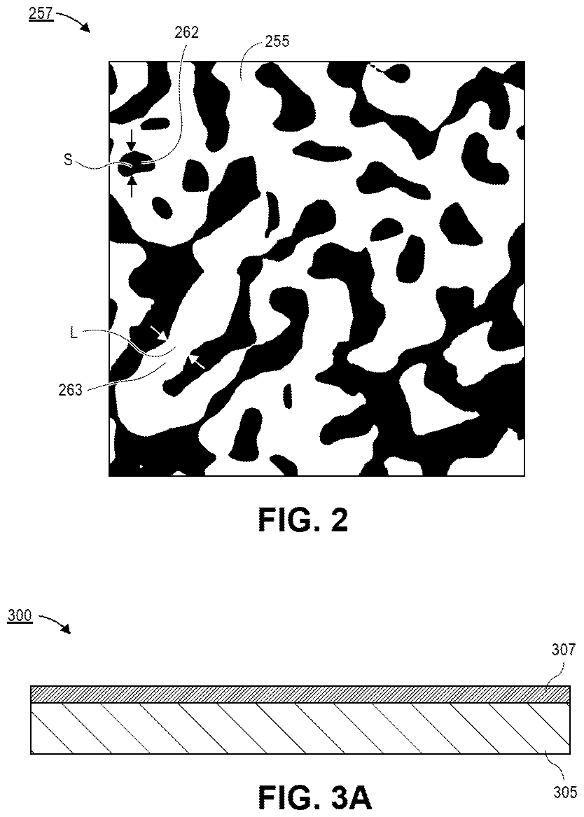

Referring now to FIG. 2, an illustrated micrograph of a nanoroughened surface 257 is shown, in accordance with an embodiment. In an embodiment, the nanoroughened surface 257 comprises a first metallic material 255 with a plurality of interconnected ligaments 263 and pores 262 between the ligaments 263. In an embodiment, an average width L of the ligaments 263 may be 50 nm or less, or 10 nm or less. In an embodiment, an average width S of the pores 262 may be 50 nm or less or 10 nm or less. As shown, the pores 262 and ligaments 263 may not have a regular and repeating pattern. That is, the pores 262 and the ligaments 263 may have a somewhat random distribution across the roughened surface 257. As such, the “frequency” of the roughened surface referred to herein may refer to an average frequency of the ligaments across a given cross-section. In some embodiments, the roughened surface 257 may be referred to as a bicontinuous nanoporous structure.

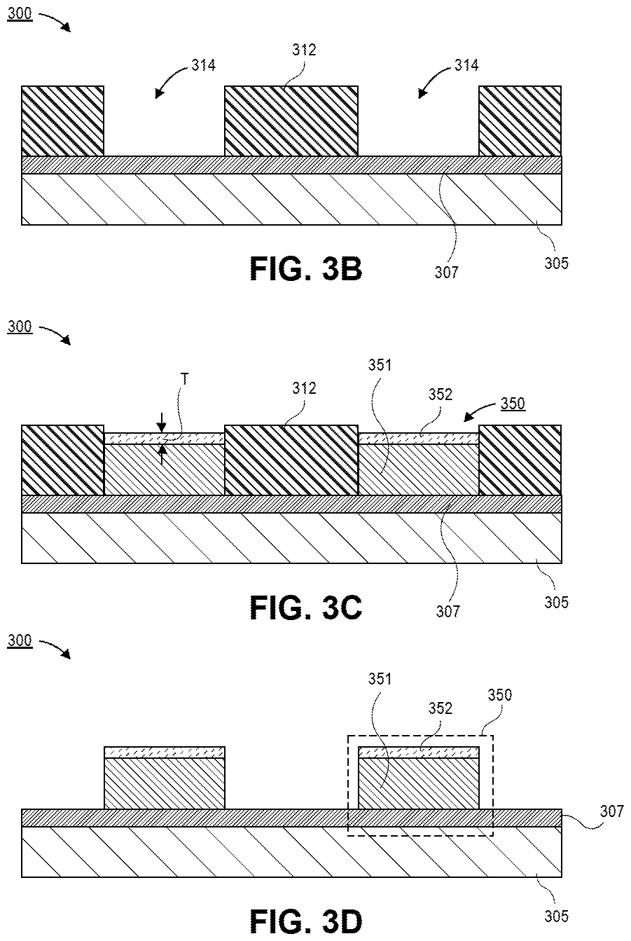

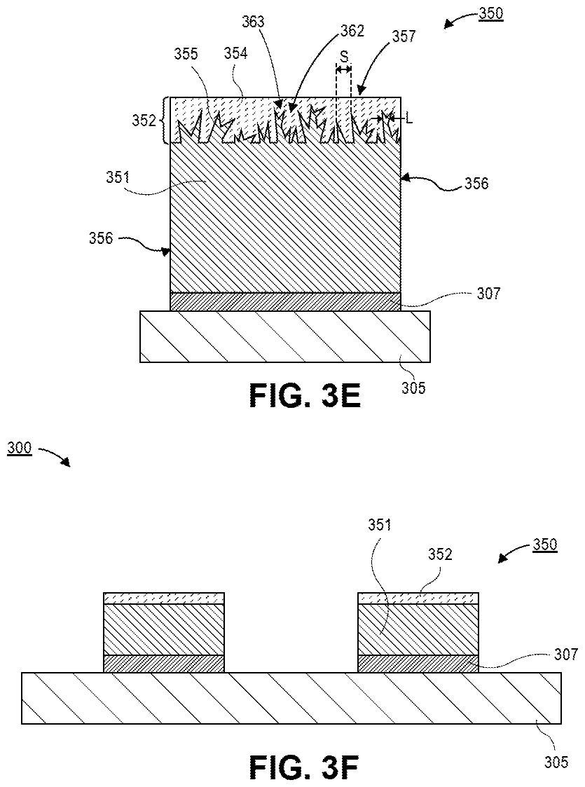

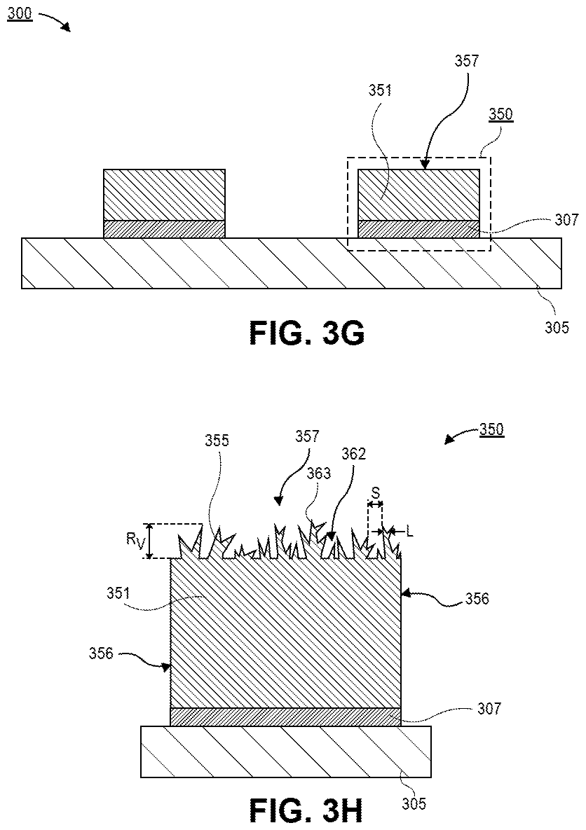

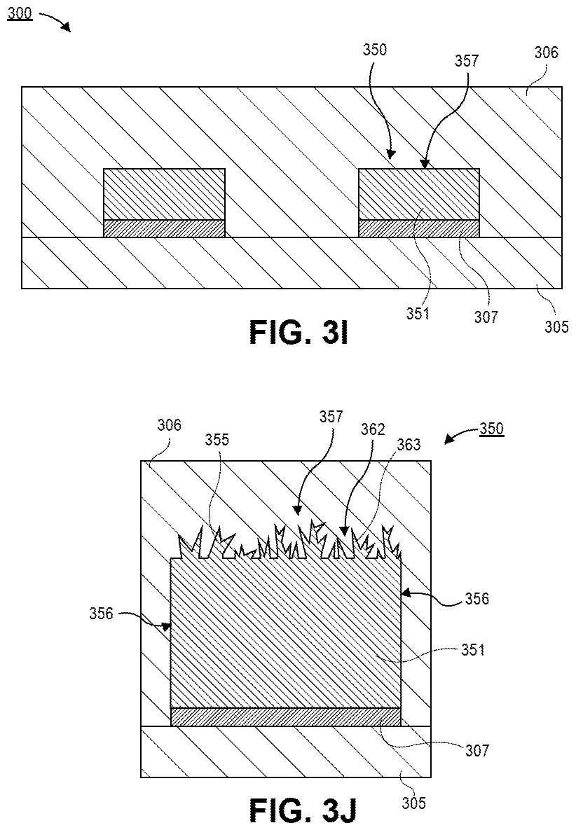

Referring now to FIG. 3A to FIG. 3J, a series of cross-sectional illustrations depicting a process for fabricating a conductive trace with a nanoroughened surface is shown, in accordance with an embodiment.

Referring now to FIG. 3A, a cross-sectional illustration of a dielectric layer 305 of an electronic package 300 is shown, in accordance with an embodiment. In an embodiment, the dielectric layer 305 may be one layer of a plurality of layers in an electronic package 300. For example, the dielectric layer 305 may be a buildup layer, a core layer, or the like.

In an embodiment, a seed layer 307 may be disposed over the surface of the dielectric layer 305. For example, the seed layer 307 may be deposited with a plating process (e.g., electrolytic or electroless plating), sputtering, or the like. In an embodiment, the seed layer 307 is blanket deposited over the entire exposed surface of the dielectric layer 305.

Referring now to FIG. 3B, a cross-sectional illustration of the electronic package 300 after a resist layer 312 is disposed over the seed layer 307 is shown, in accordance with an embodiment. In an embodiment, the resist layer 312 may be any suitable resist typically used in electronic packaging applications. For example, the resist layer 312 may be a dry film resist (DFR) or the like. In an embodiment, a plurality of openings 314 may be patterned into the resist layer 312. For example, the resist layer 312 may be patterned with a lithographic process. In an embodiment, the openings 314 expose a portion of the seed layer 307 where conductive traces, pads, or the like are desired.

Referring now to FIG. 3C, a cross-sectional illustration of the electronic package 300 after a conductive trace 350 is disposed in each of the openings 314. In an embodiment, the conductive trace 350 may comprise a main body 351 and a film 352. The main body 351 may be a first conductive material (e.g., copper), and the film 352 may be a bimetallic film that comprises a first metallic material and a second metallic material. In an embodiment, the first metallic material of the film may be the same material as the first conductive material of the main body 351. In an embodiment, the second metallic material may be a metallic material that can be selectively etched with respect to the first metallic material. For example, the second metallic material may be zinc, tin, or nickel. In FIG. 3C the film 352 is shown as a monolithic layer for simplicity. It is to be appreciated that the film 352 may comprise a structure substantially similar to the film 152 described above with respect to FIG. 1A. In an embodiment, the film 352 may have a thickness T that is 2 μm or less, 200 nm or less, 100 nm or less, or 50 nm or less.

In an embodiment, the conductive trace 350 may be deposited with an electrolytic plating process. In some embodiments, the main body 351 and the film 352 are plated in a single plating bath. For example, the plating parameters may be have a first setting to provide the main body 351, and a second setting (or second settings) that provide the film 352 comprising the first conductive material co-deposited with the second conductive material. In an embodiment, the second settings may be modulated to provide a gradient with a larger volume percentage of the first conductive material proximate to the main body 351 and a lower volume percentage of the first conductive material away from the main body 351.

Referring now to FIG. 3D, a cross-sectional illustration of the electronic package 300 after the resist layer 312 is stripped is shown, in accordance with an embodiment. In an embodiment, the resist layer 312 may be stripped with a suitable process typical of electronics packaging processes. The removal of the resist layer 312 exposes portions of the seed layer 307 between conductive traces 350.

Referring now to FIG. 3E, a cross-sectional illustration of the conductive trace 350 in FIG. 3D that provides a more detailed illustration of the film 352 is shown, in accordance with an embodiment. As shown, the conductive trace 350 comprises sidewall surfaces 356 and a top surface 357. The top surface 357 may comprise the film 352. As shown, the entire top surface is illustrated as being the second metallic material 354. However, it is to be appreciated that some portions of the top surface 357 may also comprise the first metallic material 355 in some embodiments.

In an embodiment, the film 352 comprises a first metallic material 355 and a second metallic material 354. The first metallic material 355 may comprise a plurality of ligaments 363 and pores 362. The pores 362 may be filled with the second metallic material 354. That is, the second metallic material 354 may conform to the surfaces of the first metallic material 355. In an embodiment, the pores 362 may have an average width S that is 50 nm or less, or 10 nm or less, and the ligaments 363 may have an average width L that is 50 nm or less, or 10 nm or less.

Referring now to FIG. 3F, a cross-sectional illustration of the electronic package 300 after the exposed portions of the seed layer 307 is removed is shown, in accordance with an embodiment. In an embodiment, the seed layer 307 may be removed with a flash etching process. The flash etching process may selectively remove the seed layer 307 while not significantly interacting with the conductive trace 350. Particularly, the second metallic material 354 of the film 352 may be a material that is resistant to the flash etching chemistry. As such, the film 352 provides protection from etching.

Referring now to FIG. 3G, a cross-sectional illustration of the electronic package 300 after the film 352 is selectively etched is shown, in accordance with an embodiment. In an embodiment, the film 352 may be selectively etched to remove the second metallic material. As shown in FIG. 3G, the entire film is shown as being removed for simplicity. However, it is to be appreciated that the first metallic material remains behind to provide a nanoroughened surface 357, as is shown in greater detail in FIG. 3H.

Referring now to FIG. 3H, a cross-sectional illustration of the conductive trace 350 with a nanoroughened surface 357 is shown, in accordance with an embodiment. As shown, the removal of the second metallic material leaves ligaments 363 of the first metallic material 355 exposed. The ligaments 363 also define a plurality of pores 362. In an embodiment, the ligaments 363 have an average width L that is 50 nm or less, or 10 nm or less, and the pores 362 have an average width S that is 50 nm or less or 10 nm or less. In an embodiment, an average depth of the valleys Rv (i.e., the amplitude) is 2 μm or less, 200 nm or less, or 100 nm or less. Accordingly, embodiments disclosed herein allow for a high-frequency low amplitude nanoroughened surface that is suitable for high speed signaling applications (e.g., EMIB, etc.).

In an embodiment, the top surface 357 may have a first surface roughness and sidewall surfaces 356 may have a second surface roughness that is smaller than the first surface roughness. The use of a bimetallic film 352 allows for the surface roughening to be localized to the top surface since the sidewall surfaces 356 remain protected by the resist layer 312 during the plating of the film layer 352. Accordingly, embodiments disclosed herein allow for improved electrical performance since not all surfaces of the conductive trace 350 are roughened (as is the case in existing copper roughening processes).

Referring now to FIG. 3I, a cross-sectional illustration of the electronic package 300 after a second dielectric layer 306 is disposed over the first dielectric layer 305 and the conductive traces 350 is shown, in accordance with an embodiment. In an embodiment, the second dielectric layer 306 has excellent adhesion to the conductive traces 350 due to the presence of the nanoroughened surface 357. Accordingly, embodiments disclosed herein provide improved reliability in addition to improved electrical performance.

Referring now to FIG. 3J, a cross-sectional illustration of the conductive trace 350 that more clearly illustrates the interface between the second dielectric layer 306 and the nanoroughened surface 357 is shown, in accordance with an embodiment. As shown, the second dielectric layer 306 conforms to the nanoroughened surface 357. For example, the second dielectric layer 306 substantially fills the pores 362 between the ligaments 363. Due to the high frequency of the pores 362, there is an increased amount of surface area available for the interface between the second dielectric layer 306 and the conductive trace 350. As such, the adhesion is increased.

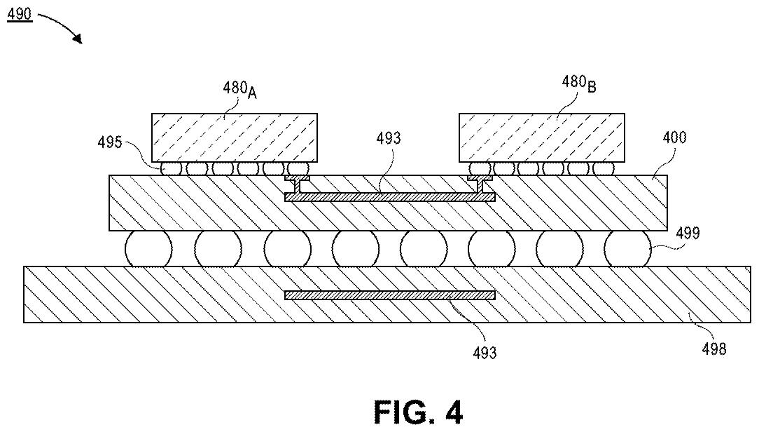

Referring now to FIG. 4, a cross-sectional illustration of a packaged system 490 is shown, in accordance with an embodiment. In an embodiment, the packaged system 490 may include a plurality of dies 480 electrically coupled to a package substrate 400 with interconnects 495. For example, the interconnects 495 may comprise C4 bumps, wire bonds, or any other suitable interconnect architecture. In an embodiment, the package substrate 400 may comprise a plurality of conductive features 493 (e.g., pads, traces, vias, and the like). In an embodiment, one or more of the conductive features may include a nanoroughened surface, such as the nanoroughened surfaces described above. In an embodiment, the conductive features 493 may be used to electrically couple a first die 480A to a second die 480B Accordingly, embodiments include a package substrate 400 that is suitable for high speed signaling applications while maintaining high reliability.

In an embodiment, the package substrate 400 may be electrically coupled to a board 498, such as a printed circuit board (PCB) with interconnects 499. For example, the interconnects 499 may comprise solder bumps, pins, or any other interconnect architecture. In an embodiment, the board 498 may comprise a plurality of conductive features 493 (e.g., pads, traces, vias, and the like). In an embodiment, one or more of the conductive features may include a nanoroughened surface, such as the nanoroughened surfaces described above. Accordingly, embodiments include a board 498 that is suitable for high speed signaling applications while maintaining high reliability.

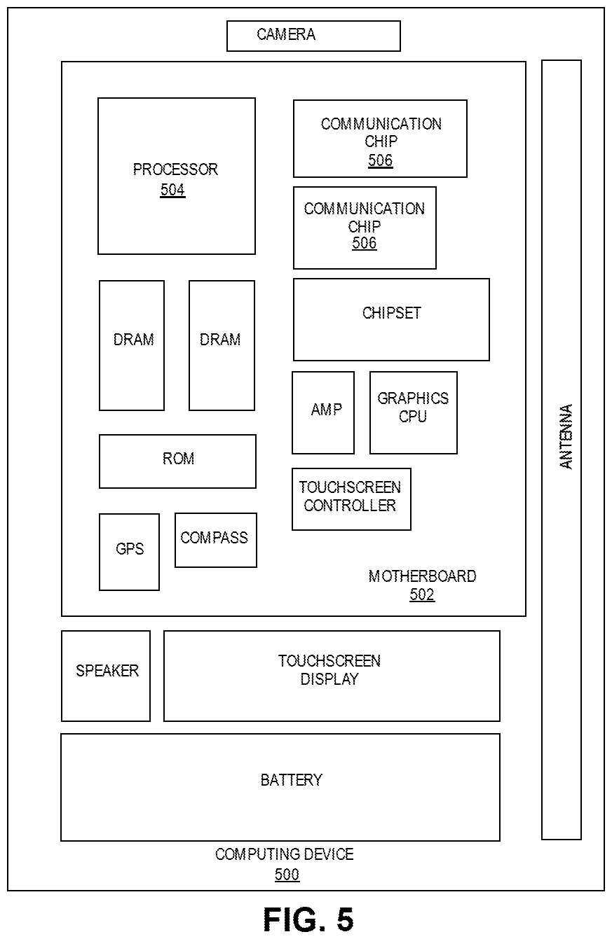

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor may be packaged in an electronic system that comprises a package substrate with conductive features that comprise a nanoroughened surface, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the invention, the integrated circuit die of the communication chip may be packaged in an electronic system that comprises a package substrate with conductive features that comprise a nanoroughened surface, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a first layer of a package substrate; and a conductive trace over the first layer of the package substrate, wherein the conductive trace comprises: a conductive body with a first surface over the first layer of the package substrate, a second surface opposite the first surface, and sidewall surfaces coupling the first surface to the second surface, wherein the second surface has a first roughness and the sidewall surfaces have a second roughness that is less than the first roughness.

Example 2: the electronic package of Example 1, wherein the first roughness comprises an average depth of valleys (Rᵥ) that is less than 2 μm.

Example 3: the electronic package of Example 1 or Example 2, wherein the first roughness comprises an Rᵥ that is less than 1 μm.

Example 4: the electronic package of Examples 1-3, wherein a frequency of the first roughness is 50 nm or less.

Example 5: the electronic package of Examples 1-4, wherein the second surface comprises a plurality of pores.

Example 6: the electronic package of Examples 1-5, wherein the second surface comprises a bicontinuous nanoporous structure.

Example 7: the electronic package of Examples 1-6, further comprising: a second layer of the package substrate over the conductive trace and the first layer of the package substrate.

Example 8: the electronic package of Examples 1-7, wherein the second layer of the package substrate conforms to the second surface of the conductive trace.

Example 9: the electronic package of Examples 1-8, further comprising: a first die over the second layer of the package substrate; and a second die over the second layer of the package substrate, wherein a conductive path between the first die and the second die comprises the conductive trace.

Example 10: the electronic package of Examples 1-9, wherein the first die is a processor.

Example 11: a method of forming an electronic package, comprising: disposing a seed layer over a first dielectric layer; disposing a resist layer over the seed layer; patterning the resist layer to provide an opening in the resist layer; disposing a conductive trace into the opening, wherein the conductive trace comprises a main body having a first metallic material, and a film over the main body, wherein the film comprises the first metallic material and a second metallic material; removing the resist layer; removing exposed portions of the seed layer; and removing the second metallic material from the film.

Example 12: the method of Example 11, wherein the first metallic material is copper, and wherein the second metallic material is zinc, tin, or nickel.

Example 13: the method of Example 11 or Example 12, wherein the film over the main body has a thickness that is less than 2 μm.

Example 14: the method of Examples 11-13, wherein removing the second metallic material from the film provides a nanoroughened surface having a plurality of pores.

Example 15: the method of Examples 11-14, wherein the film has a bicontinuous nanoporous structure.

Example 16: the method of Examples 11-15, wherein an average depth of valleys (Rv) of the film after the second metallic material is removed is less than 200 nm.

Example 17: the method of Examples 11-16, wherein the valleys have a frequency that is 50 nm or less.

Example 18: the method of Examples 11-17, wherein the main body and the film are deposited with an electrolytic plating process.

Example 19: the method of Examples 11-18, wherein the main body is plated in a first processing bath, and wherein the film is plated in a second processing bath.

Example 20: the method of Examples 11-19, wherein the main body and the film are plated in the same processing bath.

Example 21: the method of Examples 11-20, further comprising: disposing a second dielectric layer over the first dielectric layer and the conductive trace, wherein the second dielectric layer conforms to a surface of the film.

Example 22: the method of Examples 11-21, wherein the main body comprises sidewall surfaces, and wherein the film has a first surface roughness and the sidewall surfaces have a second surface roughness that is less than the first surface roughness.

Example 23: an electronic system, comprising: a board; an electronic package coupled to the board; and a die coupled to the electronic package, wherein the electronic package comprises a plurality of conductive traces electrically coupled to the die, wherein the plurality of traces each comprise: sidewall surfaces; and a top surface with a nanoroughened structure.

Example 24: the electronic system of Example 23, wherein the nanoroughened structure has a first surface roughness that is greater than a second surface roughness of the sidewall surfaces.

Example 25: the electronic system of Example 23 or Example 24, wherein the first roughness comprises an average depth of valleys (Rᵥ) that is less than 2 μm.

What is claimed is:

1. An electronic package, comprising:
a first layer of a package substrate; and
a conductive trace over the first layer of the package substrate, wherein the conductive trace comprises:
a conductive body with a first surface over the first layer of the package substrate, a second surface opposite the first surface, and sidewall surfaces coupling the first surface to the second surface, wherein the second surface has a first roughness and the sidewall surfaces have a second roughness that is less than the first roughness.

2. The electronic package of claim 1, wherein the first roughness comprises an average depth of valleys (Rᵥ) that is less than 2 μm.

3. The electronic package of claim 2, wherein the first roughness comprises an Rᵥ that is less than 1 μm.

4. The electronic package of claim 1, wherein a frequency of the first roughness is 50 nm or less.

5. The electronic package of claim 1, wherein the second surface comprises a plurality of pores.

6. The electronic package of claim 5, wherein the second surface comprises a bicontinuous nanoporous structure.

7. The electronic package of claim 1, further comprising:
a second layer of the package substrate over the conductive trace and the first layer of the package substrate.

8. The electronic package of claim 7, wherein the second layer of the package substrate conforms to the second surface of the conductive trace.

9. The electronic package of claim 7, further comprising:
a first die over the second layer of the package substrate; and
a second die over the second layer of the package substrate, wherein a conductive path between the first die and the second die comprises the conductive trace.

10. The electronic package of claim 9, wherein the first die is a processor.

11. A method of forming an electronic package, comprising:
disposing a seed layer over a first dielectric layer;
disposing a resist layer over the seed layer;
patterning the resist layer to provide an opening in the resist layer;
disposing a conductive trace into the opening, wherein the conductive trace comprises a main body having a first metallic material, and a film over the main body, wherein the film comprises the first metallic material and a second metallic material;
removing the resist layer;
removing exposed portions of the seed layer; and
removing the second metallic material from the film.

12. The method of claim 11, wherein the first metallic material is copper, and wherein the second metallic material is zinc, tin, or nickel.

13. The method of claim 11, wherein the film over the main body has a thickness that is less than 2 μm.

14. The method of claim 13, wherein removing the second metallic material from the film provides a nanoroughened surface having a plurality of pores.

15. The method of claim 14, wherein the film has a bicontinuous nanoporous structure.

16. The method of claim 14, wherein an average depth of valleys (Rᵥ) of the film after the second metallic material is removed is less than 200 nm.

17. The method of claim 16, wherein the valleys have a frequency that is 50 nm or less.

18. The method of claim 11, wherein the main body and the film are deposited with an electrolytic plating process.

19. The method of claim 18, wherein the main body is plated in a first processing bath, and wherein the film is plated in a second processing bath.

20. The method of claim 19, wherein the main body and the film are plated in the same processing bath.

21. The method of claim 11, further comprising:
disposing a second dielectric layer over the first dielectric layer and the conductive trace, wherein the second dielectric layer conforms to a surface of the film.

22. The method of claim 11, wherein the main body comprises sidewall surfaces, and wherein the film has a first surface roughness and the sidewall surfaces have a second surface roughness that is less than the first surface roughness.

23. An electronic system, comprising:
a board;
an electronic package coupled to the board; and
a die coupled to the electronic package, wherein the electronic package comprises a plurality of conductive traces electrically coupled to the die, wherein the plurality of conductive traces each comprise:
sidewall surfaces; and
a top surface with a nanoroughened structure.

24. The electronic system of claim 23, wherein the nanoroughened structure has a first surface roughness that is greater than a second surface roughness of the sidewall surfaces.

25. The electronic system of claim 24, wherein the first surface roughness comprises an average depth of valleys (Rᵥ) that is less than 2 μm.
